(19) United States
(12) Patent Application Publication
(10) Pub. No.: US 2026/0180311 A1
(43) Pub. Date: Jun. 25, 2026

(54) TEMPERATURE ESTIMATION FOR POWER ELECTRONICS

(71) Applicant: Eaton Intelligent Power Limited, Dublin (IE)

(72) Inventors: Sachin Patil, Pune (IN); Sauradeep Datta, Pune (IN); Derek Dougherty, Fruitport, MI (US); Pratik Katolkar, Pune (IN); Ravi Patel, Gujarat (IN)

(73) Assignee: Eaton Intelligent Power Limited, Dublin (IE)

(21) Appl. No.: 19/419,457

(22) Filed: Dec. 15, 2025

(30) Foreign Application Priority Data
Dec. 19, 2024 (IN) 202411100834

(51) Int. Cl. H02H 7/10; G01K 7/42; H02M 1/32; H05K 7/20

(52) U.S. Cl. CPC H02H 7/10; G01K 7/427; H02M 1/327; H05K 7/20209; H05K 7/20909; H05K 7/20945; G01K 2205/00

(57) ABSTRACT

Systems and methods for temperature monitoring in power electronics determine at least one temperature based on operational characteristics of the power electronics system. The operational characteristics are used to determine a power loss using a model of the power electronics system. The power loss is used to determine the temperature using a thermal model of the power electronics system. The temperature can be used to control the power electronics system, for example by allowing control over cooling such as controlling fan speeds, compensating for temperature effects on the power electronics system or components thereof, or shutting down components or systems when overheating is detected.

### CROSS-REFERENCE TO RELATED APPLICATION

This application claims the benefit of Indian Application No. 202411100834, filed Dec. 19, 2024, the disclosure of which is hereby incorporated by reference in its entirety.

### BACKGROUND

In power electronics such as inverters, controllers for systems including electrically powered motors, and the like, temperatures can be monitored using on-board temperature sensors. Such monitoring can be used to provide overtemperature protection and/or to provide compensation for temperature effects on electronics performance. The on-board temperature sensors can be difficult to implement, and can increase cost, power consumption, or board footprint. Such temperature sensors also can be an additional point of failure, lowering mean times between failure for components and making certification of components more difficult for applications such as aerospace applications. In the absence of such temperature sensors, cooling systems can be run at fixed values to prevent overheating, which can cause unnecessary wear on components such as cooling fans.

### SUMMARY

The present disclosure is directed to monitoring of temperatures in power electronics systems, particularly using models to calculate temperatures based on operational conditions of the system.

Temperature monitoring according to embodiments described herein can allow temperature determination even in systems that do not include on-board temperature sensors. This can allow for more precise control of cooling and/or taking remedial actions such as shutting down components when overheat conditions are detected. Temperature monitoring according to embodiments can provide the temperature response capabilities without the cost, complexity, or space requirements of on-board temperature sensors. In some embodiments, the temperature monitoring can be used in addition to temperature sensors such as on-board temperature sensors, separate temperature sensors such as resistance temperature detectors or negative temperature coefficient thermistors, or the like to provide redundancy and/or to provide awareness of temperature conditions in areas where the temperature sensors cannot be provided.

In an embodiment, the temperature monitoring can be used to control cooling systems to reduce wear on such cooling systems, for example, throttling fan speeds when the temperatures are within acceptable ranges. The reduction of wear on cooling systems can increase the mean time between failures (MTBF) for a reliability-critical part, thus increasing the MTBF for a device as a whole where the cooling systems are a limiting factor for reliability.

In an embodiment, a temperature monitoring system includes one or more processors and one or more memories. The one or more memories store instructions that, when executed, cause the one or more processors to receive operational characteristics of a power electronics system. The instructions further cause the one or more processors to determine, based on the operational characteristics and a model of the power electronics system, an estimated power loss for the power electronics system. The instructions also cause the one or more processors to determine, based on the estimated power loss and a thermal model of the power electronics system, at least one temperature associated with the power electronics system, the at least one temperature including an air temperature within a housing of the power electronics system or a junction temperature within the power electronics system. The instructions further cause the one or more processors to control operation of the power electronics system based on the at least one temperature.

In an embodiment, a method for temperature monitoring includes receiving, at a processor, operational characteristics of a power electronics system. The method further includes determining, based on the operational characteristics and a model of the power electronics system, an estimated power loss for the power electronics system. The method also includes determining, based on the estimated power loss and a thermal model of the power electronics system, at least one temperature associated with the power electronics system, the at least one temperature including an air temperature within a housing of the power electronics system or a junction temperature within the power electronics system. The method also includes controlling operation of the power electronics system based on the at least one temperature.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 shows a flowchart for a method for temperature monitoring according to an embodiment.

FIG. 2 shows a schematic of a power electronics system according to an embodiment.

FIG. 3 shows logical components of a temperature monitoring system according to an embodiment.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

Temperature monitoring according to embodiments described herein can enable the determination of temperatures even in the absence of temperature sensors in the device. The temperature determinations can allow for control of the system, such as control of cooling systems, triggering remedial actions such as shutdown in response to overheat conditions, compensation for temperature effects, or the like. In an embodiment, the temperature monitoring can be used to determine junction temperatures affecting performance in power electronics. The temperature monitoring can be used to control cooling systems to limit wear, with an example of such control being the throttling of fans when temperature conditions allow, thereby increasing an overall MTBF by reducing the intensity of operation of a reliability-critical component. The temperature monitoring can be determined based on known operational characteristics, thus not requiring additional sensors to provide inputs for the estimation of the temperature.

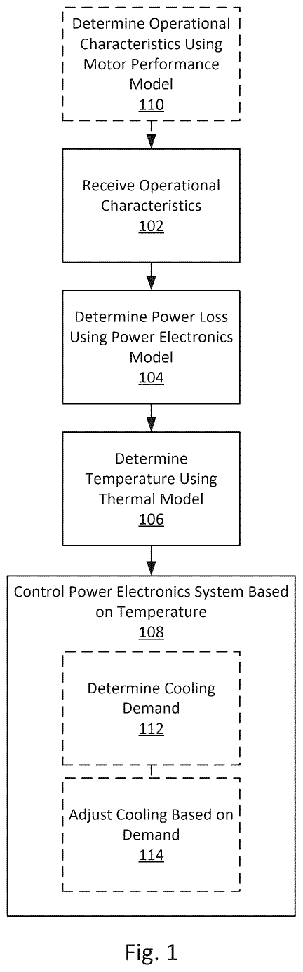

FIG. 1 shows a flowchart for a method for temperature monitoring according to an embodiment. Method 100 includes receiving operational characteristics of a power electronics system 102, determining an estimated power loss based on the operational characteristics using a power electronics model 104, determining a temperature based on the estimated power loss using a thermal model 106, and controlling operation of the power electronics system at 108. Optionally, method 100 can include deriving at least some of the operational characteristics based on a motor performance model 110.

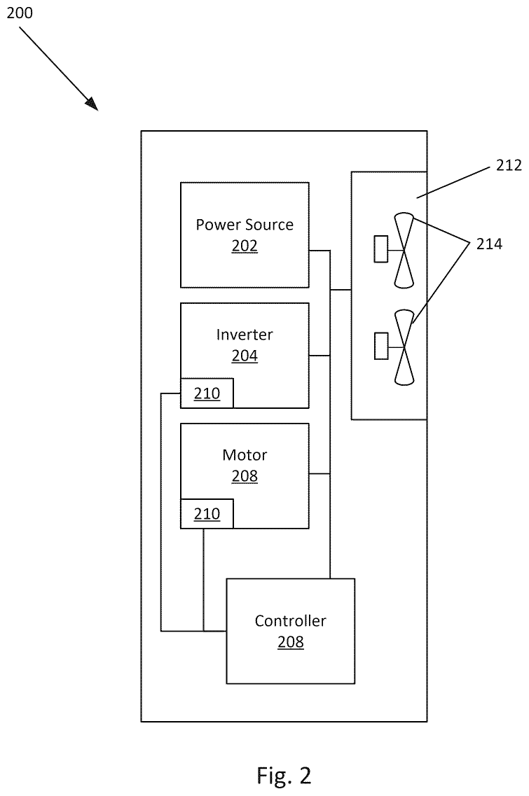

Method 100 is a method for determining a temperature based on operational characteristics of a power electronics system, such as an electrically powered compressor, pump, hydraulic power pack, traction motor, or the like. The method 100 can be performed using a controller included in the system, such as controller 208 of the power electronics system 200 as described below and shown in FIG. 2. In embodiments, the method 100 can be performed continuously to monitor temperatures or performed at predetermined sampling intervals. In an embodiment, the method 100 can include feedback between steps, such as providing cooling system data such as fan speeds as an input to the thermal model when the control of operation of the power electronics system at 108 includes adjusting operation of a cooling system.

Operational characteristics of a power electronics system are received at 102. The operational characteristics can be conditions relevant to the demand on the power electronics system. For example, in an embodiment where the power electronics system is an electrically powered hydraulic power pack, the operational characteristics can include flow demand from the hydraulic power pack, an ambient pressure in the environment around the hydraulic power pack, and a bay temperature of the hydraulic power pack. In an embodiment, the operational characteristics can include a volume or power demand for a pump or compressor, power demand for a traction motor or electrically powered actuator, power draw from an inverter or uninterruptible power supply (UPS) or the like. In an embodiment, the operational characteristics include a commanded operating point of an electric motor. In an embodiment, the operational characteristics can include a current draw by an electric motor, and a voltage applied to said electric motor. In an embodiment, the operational characteristics received at 102 can be derived at 110 using a motor performance model.

An estimated power loss is determined based on the operational characteristics using a power electronics model at 104. The power electronics model is a mathematical model configured to calculate the estimated power loss based on the operational characteristics received at 102. The power electronics model can be a model determined based on testing of the power electronics system, simulations, finite element analysis (FEA), known component characteristics for example from manufacturer datasheets, combinations thereof, or the like. The power electronics model can be a static model that is determined in advance and stored in a memory of a controller performing method 100 in a power electronics system. The estimated power loss is an estimate of the power that will be consumed within the power electronics system, for example due to circuit components included therein such as resistors, transistors such as a metal oxide semiconductor field effect transistors (MOSFETs), diodes, combinations thereof, and the like. In an embodiment, the power electronics model can accept a junction temperature as an input and be configured to account for the junction temperature in determining the estimated power loss. The junction temperature can be a junction temperature as determined by the thermal model based on the power loss art 108 determined previously according to method 100, for example the most recent junction temperature in continuous monitoring, a junction temperature as determined in a previous iteration of method 100, or the like.

One or more temperatures are determined based on the estimated power loss at 106. The estimated power loss can be the output from the power electronics model determined at 104. The one or more temperatures are determined at 106 based on a thermal model. The thermal model can be a predictive thermal model, such as a model generated by computational fluid dynamics (CFD), a one-dimensional (1-D) thermal model, a thermal model generated by finite element analysis FEA, or the like. In an embodiment, the thermal model is the 1-D thermal model. The thermal model can be a predetermined model stored in a memory of the controller. The thermal model can determine, based on the estimated power loss, the generation of heat within the power electronics system. The generation of heat can in turn be used by the thermal model to derive temperatures within the power electronics system, for example based on, for example, known or assumed heat generation and/or dissipation of components, housings and the like, cooling of the power electronics system such as airflows driven by cooling fans, other airflows, other heat transfer occurring within the device or system, and the like. The temperatures determined at 106 include one or more temperatures associated with the power electronics system, such as, for example, a temperature of a housing of the power electronics system, one or more junction temperatures of junctions within the power electronics system, a hermetic air temperature within the power electronics system, or the like.

In an embodiment, the method 100 includes controlling operation of the power electronics system at 108. The control of operation of the power electronics system at 108 is based on one or more of the temperatures determined at 106. A non-limiting example of control of operation of the power electronics system at 108 is shutting down one or more components of the power electronics system in response to one or more of the temperatures exceeding a threshold indicative of an overheating condition. Another non-limiting example of control of the power electronics system at 108 is controlling one or more components based on a junction temperature determined at 106 to account for performance changes associated with the junction temperature.

In the example shown in FIG. 1, controlling the operation of the power electronics system at 108 includes determining cooling demand 112 and adjusting cooling based on the cooling demand 114. The determination of cooling demand at 112 can be based on one or more of the temperatures determined at 106, for example by comparing the one or more temperatures to one or more thresholds, using a formula accepting the one or more temperatures as input, referencing a lookup table, or the like. The cooling demand determined at 112 can indicate the cooling demand to maintain acceptable temperatures within the power electronics system or at one or more components thereof. Cooling can be adjusted at 114 based on the cooling demand. The adjustment of cooling at 114 can be, for example, reducing a speed of one or more cooling fans of a cooling system, deactivating one or more cooling fans, or the like to meet the cooling demand while reducing excess cooling capacity. In an embodiment, the adjustment of cooling at 114 is a throttling of fan speeds, thereby reducing wear resulting from full-speed fan operation. The operational parameters of the cooling system following adjustment of operations at 114 can be provided as an input to the thermal model for future iterations of the method 100, for example providing a fan flowrate to the thermal model such that the current operations of the cooling system are properly represented in the thermal system when determining temperatures at 106.

Optionally, method 100 can include deriving at least some of the operational characteristics based on a motor performance model 110. For example, a motor performance model can be used to derive one or more of a motor current, an applied voltage to the motor, or the like based on one or more inputs such as motor speed, ambient temperature, a junction temperature determined at 108, combinations thereof, and the like. The motor performance model can be derived from, as none-limiting examples, empirical testing of the motors, the design and component selection of the motor, published characteristics for the motor such as manufacturer data sheets, simulations of motor performance, combinations thereof, or the like. The motor performance model can be a predetermined model stored in memory of the controller performing method 100.

FIG. 2 shows a schematic of a power electronics system according to an embodiment. Power electronics system 200 includes power source 202, inverter 204, motor 206, and controller 208. In an embodiment, one or more temperature sensors 210 can be provided in power electronics system 200. In an embodiment, power electronics system 200 includes cooling system 212, with cooling system 212 including fans 214.

The example power electronics system 200 is a device including an electrically powered motor 206 powered by power source 202. Non-limiting examples of such a power electronics system 200 include electrically powered pumps such as fuel or hydraulic pumps, compressors, actuators such as control surface actuators for aerospace applications, electric traction motors, or the like. In an embodiment, the power electronics system 200 is an electrically powered hydraulic power pack.

Power source 202 is a source of electrical power for the power electronics system 200. Power source 202 can be, for example, one or more batteries. Power source 202 can be a source of direct current (DC) power. Power source 202 can be configured to supply sufficient voltage and current to inverter 204 such that alternating current (AC) power output by inverter 204 is sufficient to drive motor 206. Inverter 204 is configured to receive DC power from power source 202 and output suitable AC power so as to drive operation of motor 206. Motor 206 is an electric motor powered by AC power output from inverter 204. The motor 206 can drive operation of the power electronics system 200, for example driving a pump, compressor or actuator, providing motive force from an electric traction motor, or the like.

Controller 208 is configured to control operation of one or more of power source 202, inverter 204, drive motor 206, and/or cooling system 212. Controller 208 can be configured to receive inputs of operational characteristics of the power electronics system 200. The controller 208 includes one or more processors 216 and one or more memories 218. The one or more memories 218 are configured to store program instructions and models for performing temperature monitoring, for example the power electronics mode, the thermal model, and instructions directing performance of, for example, method 100 as described above and shown in FIG. 1. The one or more memories 218 can further include program instructions for controlling operations in response to the determined temperature, for example to control inverter 204 and/or drive motor 206 to adjust or cease operations based on the determined temperature, to control cooling system 212 or fans 214 thereof, or the like. In an embodiment, the one or more memories 218 include program instructions controlling the speed of the fans 214 based on the determined temperature, so as to operate the fans at levels sufficient to maintain suitable temperatures without providing excessive cooling.

In an optional embodiment, one or more temperature sensors 210 can be included in power electronics system 200, for example at or on a circuit board of inverter 204, at or near power source 202, at or near motor 206, on or within a housing containing at least some components of power electronics system 200, or the like. The temperature sensors 210 can be connected to controller 208 to provide temperature readings from the respective locations thereof. In another embodiment, no temperature sensors 210 are included in the power electronics system 200. In an embodiment, no temperature sensors 210 are provided on circuit boards included in power source 202, inverter 204, and/or motor 206 included within the power electronics system 200.

When the optional temperature sensors 210 are included, controller 208 can be further configured to control operations of the power electronics system 200 based on the readings from the temperature sensors 210. In an embodiment, readings from the temperature sensors 210 can be used for at least some of the same temperatures as being determined at controller 208, thereby providing redundancy. In an embodiment, the temperature sensors 210 can serve as backup for temperature determination by controller 208. In an embodiment, determinations of temperature at controller 208 can serve as backup to the temperature sensors 210. Such redundancy can allow operation of power electronics system 200 to continue even if a failure is experienced by one or more of the temperature sensors 210. In an embodiment, at least some of temperature sensors 210 can measure temperatures not determined by controller 208, providing additional temperature data. The additional temperature data can be used by controller 208 when controlling one or more components of the power electronics system 200. In an embodiment, the additional temperature data and temperatures determined by the controller 208 can both be used in controlling elements of the power electronics system 200.

In the embodiment shown in FIG. 2, the power electronics system 200 includes a cooling system 212. Cooling system 212 is configured to provide cooling to at least some components of the power electronics system 200. The cooling system can be, for example, an air-cooling system configured to direct a cooling airflow through a housing of the power electronics system, a fluid cooling system configured to circulate a cooling fluid to one or more components of the power electronics system 200, or the like. The cooling system can include one or more fans 214 configured to drive airflow, for example to provide the cooling airflow, to direct airflows over a radiator for the cooling fluid, or the like. In an embodiment, the fans 214 can be controlled by the controller 208 based on determined or measured temperatures. In an embodiment, controller 208 can control cooling system 212 to correspond to the cooling demand indicated by the temperatures within power electronics system 200, for example reducing the cooling provided by cooling system 212 to correspond to the cooling demand indicated by the temperatures determined at controller 208 and/or temperatures received from optional temperature sensors 210. For example, the speed of fans 214 can be throttled when the cooling capacity of cooling system 212 is not fully required to maintain suitable temperatures. Controller 208 can be configured to control other elements of cooling system 212 based on temperature, such as a pump circulating cooling fluid, or the like.

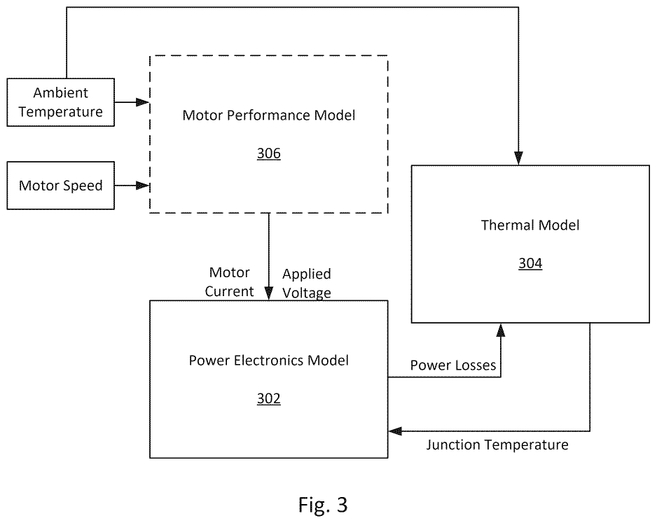

FIG. 3 shows logical components of a temperature monitoring system according to an embodiment. The logical components of the temperature monitoring system 300 include power electronics model 302, thermal model 304, and optionally motor performance model 306.

Logical components of the temperature monitoring system 300 are models that can be stored in memories and used by processors of a controller in a power electronics device or system, such as controller 208 of power electronics system 200. The models can be stored in one or more memories, such as the memories 218 of the controller 208. The controller 208 can use the models at respective steps when performing temperature monitoring, for example according to the method 100 as described above and shown in FIG. 1.

Power electronics model 302 is a mathematical model configured to determine power losses within a power electronics system based on operational characteristics of the power electronics system. The operational characteristics can include voltages and currents in the power electronics system, such as an applied voltage, a motor current, and the like. The operational characteristics can optionally include parameters indicative of loading of the power electronics system, such as, for a hydraulic power pack, the flow demand, ambient pressure, and bay temperature as obtained for a duty cycle of the hydraulic power pack. In an embodiment, power electronics model 302 can receive such parameters indicative of loading directly to determine the power loss within the power electronics system. In an embodiment, the optional motor performance model 306 can determine voltages and currents to be input into power electronics model 302 for the determination of the power loss, as described below. The power electronics model 302 can be a model derived from one or more of simulations of device performance, fact sheets for the device or components thereof developed by a manufacturer, characteristics of the components and the arrangement thereof in the power electronics system, finite element analysis, combinations thereof, or the like. In an embodiment, the power electronics model 302 can output power losses for each of a plurality of circuits provided in a power electronics system based on the input of the operational characteristics. In an embodiment, the power electronics model can accept as inputs one or more junction temperatures determined using the thermal model 304.

Thermal model 304 is a mathematical model configured to determine one or more temperatures within the power electronics system based on inputs including power losses within the system as determined from power electronics model 302, and optionally ambient temperatures, operation of cooling systems, and the like. The temperatures output by thermal model 304 can be estimated temperatures for one or more positions or components within the power electronics system, such as a temperature of a junction in the power electronics system, a temperature at or within a housing of the power electronics system, a temperature at a circuit board of an inverter, a temperature at a motor, a temperature of a power supply such as a batter, or the like. Thermal model 304 can be a predictive thermal model, such as a thermal model generated by FEA or CFD. In an embodiment, the thermal model 304 is a 1-D thermal model. The thermal model 304 can be derived based on characteristics of the power electronics system such as known or assumed heat generation and/or dissipation of components, housings and the like, cooling of the power electronics system such as airflows driven by cooling fans, and the like. In an embodiment, the thermal model 304 can accept operational characteristics of a cooling system, such as fan speed, cooling capacity being delivered, or the like as an input. In an embodiment, the operational characteristics of the cooling system can be provided from a controller directing operation of the cooling system, such as the controller 208 described above and shown in FIG. 2.

Motor performance model 306 can optionally be included among the logical components 300. Motor performance model 306 can be a mathematical model configured to determine suitable inputs for the power electronics model 302 based on operation of the power electronics system. For example, where power electronics model 302 is configured to receive an applied voltage and a motor current as the operational parameters used to determine power loss, the motor performance model 306 can be a mathematical model configured to determine the applied voltage and a motor current based on the operation of the power electronics system, for example parameters indicative of loading of the power electronics system. In an example where the power electronics system is a hydraulic power pack, the motor performance model can be configured to determine the operational characteristics input into power electronics model 302 based on parameters such as the flow demand, ambient pressure, and bay temperature as obtained for a duty cycle of the hydraulic power pack. The motor performance model 306 can be derived based on, for example, models and/or simulations of the performance of the power electronics system or components thereof, manufacturer fact sheets or other sources of knowledge regarding the characteristics of particular components, the selection and arrangement of components in the power electronics system, combinations thereof, and the like.

### ASPECTS OF THE DISCLOSURE

It is understood that any of aspects 1-10 can be combined with any of aspects 11-20.

Aspect 1. A temperature monitoring system, comprising:
one or more processors; and
one or more memories, the one or more memories storing instructions that, when executed, cause the one or more processors to:
receive operational characteristics of a power electronics system;
determine, based on the operational characteristics and a model of the power electronics system, an estimated power loss for the power electronics system;
determine, based on the estimated power loss and a thermal model of the power electronics system, at least one temperature associated with the power electronics system, the at least one temperature including an air temperature within a housing of the power electronics system or a junction temperature within the power electronics system; and control operation of the power electronics system based on the at least one temperature.

Aspect 2. The temperature monitoring system according to aspect 1, wherein the thermal model is a one-dimensional heat transfer model.

Aspect 3. The temperature monitoring system according to aspect 1 or aspect 2, wherein the instructions further cause the one or more processors to determine at least some of the operational characteristics of the power electronics system based on a received ambient temperature, a received motor speed, and a motor performance model.

Aspect 4. The temperature monitoring system according to any of aspects 1-3, wherein the instructions cause the one or more processors to control operation of the power electronics system by directing deactivation of the power electronics system.

Aspect 5. A power electronics system including the temperature monitoring system according to any of aspects 1-4.

Aspect 6. The power electronics system according to aspect 5, further comprising one or more fans, wherein the one or more processors are configured to control operation of the power electronics system by adjusting an operating speed of at least one of the one or more fans.

Aspect 7. The power electronics system according to aspect 5 or aspect 6, wherein the power electronics system is a hydraulic power pack including a power source, an inverter, and a motor.

Aspect 8. The power electronics system according to aspect 7, wherein the operational characteristics include a flow demand, an ambient pressure, and a bay temperature for the hydraulic power pack.

Aspect 9. The power electronics system according to any of aspects 1-8, further comprising one or more temperature sensors.

Aspect 10. The power electronics system according to any of aspects 1-8, wherein the power electronics system does not include a temperature sensor.

Aspect 11. A method for temperature monitoring, comprising:
receiving, at a processor, operational characteristics of a power electronics system;
determining, based on the operational characteristics and a model of the power electronics system, an estimated power loss for the power electronics system;
determining, based on the estimated power loss and a thermal model of the power electronics system, at least one temperature associated with the power electronics system, the at least one temperature including an air temperature within a housing of the power electronics system or a junction temperature within the power electronics system; and
controlling operation of the power electronics system based on the at least one temperature.

Aspect 12. The method according to aspect 11, wherein controlling the operation of the power electronics system based on the at least one temperature includes controlling one or more cooling fans of the power electronics system.

Aspect 13. The method according to aspect 12, wherein controlling the one or more cooling fans includes reducing a speed of at least one of the one or more cooling fans.

Aspect 14. The method according to any of aspects 11-13, wherein controlling the operation of the power electronics system includes deactivating the power electronics system.

Aspect 15. The method according to any of aspects 11-14, wherein the thermal model of the power electronics system is a one-dimensional heat transfer model.

Aspect 16. The method according to any of aspects 11-15, further comprising determining the operational characteristics of the power electronics system based on a motor speed, an ambient temperature, and a motor performance model.

Aspect 17. The method according to aspect 16, wherein the operational characteristics of the power electronics system include a current supplied to a motor and an applied voltage.

Aspect 18. The method according to any of aspects 11-17, wherein the operational characteristics of the power electronics system include the junction temperature.

Aspect 19. The method according to any of aspects 11-18, further comprising detecting at least one temperature in the power electronics system using at least one temperature sensor.

Aspect 20. The method according to any of aspects 11-18, wherein the power electronics system does not include a temperature sensor.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A temperature monitoring system, comprising:
one or more processors; and
one or more memories, the one or more memories storing instructions that, when executed, cause the one or more processors to:
receive operational characteristics of a power electronics system;
determine, based on the operational characteristics and a model of the power electronics system, an estimated power loss for the power electronics system;
determine, based on the estimated power loss and a thermal model of the power electronics system, at least one temperature associated with the power electronics system, the at least one temperature including an air temperature within a housing of the power electronics system or a junction temperature within the power electronics system; and
control operation of the power electronics system based on the at least one temperature.

2. The temperature monitoring system of claim 1, wherein the thermal model is a one-dimensional heat transfer model.

3. The temperature monitoring system of claim 1, wherein the instructions further cause the one or more processors to determine at least some of the operational characteristics of the power electronics system based on a received ambient temperature, a received motor speed, and a motor performance model.

4. The temperature monitoring system of claim 1, wherein the instructions cause the one or more processors to control operation of the power electronics system by directing deactivation of the power electronics system.

5. A power electronics system including the temperature monitoring system of claim 1.

6. The power electronics system of claim 5, further comprising one or more fans, wherein the one or more processors are configured to control operation of the power electronics system by adjusting an operating speed of at least one of the one or more fans.

7. The power electronics system of claim 5, wherein the power electronics system is a hydraulic power pack including a power source, an inverter, and a motor.

8. The power electronics system of claim 7, wherein the operational characteristics include a flow demand, an ambient pressure, and a bay temperature for the hydraulic power pack.

9. The power electronics system of claim 5, further comprising one or more temperature sensors.

10. The power electronics system of claim 5, wherein the power electronics system does not include a temperature sensor.

11. A method for temperature monitoring, comprising:
receiving, at a processor, operational characteristics of a power electronics system;
determining, based on the operational characteristics and a model of the power electronics system, an estimated power loss for the power electronics system;
determining, based on the estimated power loss and a thermal model of the power electronics system, at least one temperature associated with the power electronics system, the at least one temperature including an air temperature within a housing of the power electronics system or a junction temperature within the power electronics system; and
controlling operation of the power electronics system based on the at least one temperature.

12. The method of claim 11, wherein controlling the operation of the power electronics system based on the at least one temperature includes controlling one or more cooling fans of the power electronics system.

13. The method of claim 12, wherein controlling the one or more cooling fans includes reducing a speed of at least one of the one or more cooling fans.

14. The method of claim 11, wherein controlling the operation of the power electronics system includes deactivating the power electronics system.

15. The method of claim 11, wherein the thermal model of the power electronics system is a one-dimensional heat transfer model.

16. The method of claim 11, further comprising determining the operational characteristics of the power electronics system based on a motor speed, an ambient temperature, and a motor performance model.

17. The method of claim 16, wherein the operational characteristics of the power electronics system include a current supplied to a motor and an applied voltage.

18. The method of claim 11, wherein the operational characteristics of the power electronics system include the junction temperature.

19. The method of claim 11, further comprising detecting at least one temperature in the power electronics system using at least one temperature sensor.

20. The method of claim 11, wherein the power electronics system does not include a temperature sensor.
